(19) United States
(12) Patent Application Publication
(10) Pub. No.: US 2004/0244686 A1
(43) Pub. Date: Dec. 9, 2004

(54) Surface treatment system, surface treatment method and product produced by surface treatment method

(76) Inventors: Cheon-Soo Cho, Changwon (KR); Dong-Sik Youn, Changwon (KR); Hyun-Wook Lee, Gimhae (KR); Samchul Ha, Changwon (KR); Hyun-Woo Jun, Changwon (KR)

Correspondence Address: BIRCH STEWART KOLASCH & BIRCH, PO BOX 747, FALLS CHURCH, VA, 22040-0747, US

(21) Appl. No.: 10/486,032

(22) PCT Filed: Dec. 30, 2002
(86) PCT No.: PCT/KR02/02491

(30) Foreign Application Priority Data
Mar. 29, 2002 (KR) 10-2002-0017509

(51) Int. Cl. C23C 16/00

(52) U.S. Cl. 118/719

(57) ABSTRACT

A surface treatment system (200) comprises a conveying unit (100) for loading and conveying an object of surface treatment including one or more members which are already processed; and a surface treatment unit for forming a deposition layer on a surface of the object of surface treatment conveyed by the conveying unit (100) using a chemical vapor deposition (CVD) reaction. Thereby, massive surface treatment can be performed so as to form deposition layer on entire surface of members constructing a product by performing the surface treatment forming the deposition layer on the product continuously, and therefore, function of the product can be improved.

### TECHNICAL FIELD

The present invention relates to a surface treatment of a product, and particularly, to a surface treatment system, a surface treatment method and a product produced by the surface treatment method.

### BACKGROUND ART

In general, a surface treatment is to make a surface of a product made of a material such as a metal look good, or to improve a surface to have heat resistance, corrosion resistance, abrasion resistance, etc. so that a function of the product can be improved according to a condition of usage of the product.

Meanwhile, a heat exchanger used in an air conditioner, a refrigerator, a heating device, etc. is a device for transmitting heat from fluid of high/low temperature to fluid of low/high temperature through a heat transmitting wall. A status of the surface on the heat transmitting wall greatly affects to the heat exchanging efficiency of the heat exchanger, such that the flowing of the fluid can be varied according to the status of the surface on the heat transmitting wall.

Therefore, it is necessary to improve properties of the surface on the heat transmitting wall so as to improve the heat exchanging efficiency, and accordingly, fins constructing the heat exchanger are produced by processing a sheet material having a surface which is treated to have hydrophilicity, hydrophobicity or corrosion resistance, etc.

In addition, the sheet material for manufacturing fins constructing the heat exchanger undergoes surface treatment process forming a deposition layer on the surface of the sheet material using a chemical vapor deposition reaction or a physical vapor deposition reaction.

FIG. 1 is a plane view showing a general heat exchanger used in a refrigerator.

As shown in FIG. 1, the general heat exchanger used in the refrigerator as an example of the heat exchanger 10 comprises a refrigerant pipe 11 having a passage of refrigerant, a pair of fixing members 12 for fixing the refrigerant pipe 11, and a plurality of fins 13 fixedly installed on the refrigerant pipe 11 with some intervals therebetween for heat exchange.

The refrigerant in low temperature flowing on the refrigerant pipe 11 of the heat exchanger 10 cools down the air flowing on the surface of the heat exchanger 10, and the cooled air maintains temperatures of a cooling chamber or a freezing chamber of the refrigerator in preset temperature. Generally, dewdrops are generated on the surface of the heat exchanger 10 by cooling down the air, and the dewdrops on the surface of the heat exchanger 10 forms ices. Then, the ices are grow larger and larger to narrow the passage of the air and to reduce contacting area between the air and the surface of the heat exchanger 10, and thereby, efficiency of the refrigerator is lowered.

Therefore, the heat exchanger 10 uses a plurality of fins 13 after processing plate materials which are treated to have hydrophilicity to prevent the dewdrops from being stayed on the fin 13 of the heat exchanger 10, and thereby, the efficiency of the refrigerator can be improved.

However, during the process of fabricating the surface treated sheet materials into the fins for the heat exchanger, cut surface and the deposition layer may be damaged, or the fins are assembled some parts which are not treated may be generated and the dewdrops are generated on that parts.

That is, the member, which is surface treated to perform good function when it is used, may be damaged its surface in fabricating process such as molding fabrication or assembling fabrication to become a product, or the member may be assembled with other member of which surface is not treated, and accordingly, the function improvement effect of the product according to the surface treatment is reduced.

### DISCLOSURE OF THE INVENTION

Therefore, it is an object of the present invention to provide a surface treatment system and a surface treatment method by which a massive surface treatment is performed so that deposition layer can be formed on entire surfaces of members which are included in a product, by treating surfaces of a product including one or more members for forming the deposition layer.

To achieve the object of the present invention, there is provided a surface treatment system comprising: a conveying unit for carrying and conveying an object of surface treatment which includes one or more processed members; and a surface treatment unit forming a deposition layer on a surface of the object of surface treatment which is conveyed by the conveying unit using a chemical vapor deposition (CVD) reaction.

Also, to achieve the object of the present invention, there is provided a surface treatment system comprising: a conveying unit for carrying and conveying an object of surface treatment including one or more processed members; and a surface treatment unit forming a deposition layer on a surface of the object of surface treatment which is conveyed by the conveying unit using a physical vapor deposition (PVD) reaction.

Also, there is provided a surface treatment method comprising: a conveying step of loading and conveying a product produced using one or more members; and a deposition layer forming step forming a deposition layer on a surface of the conveyed product using a CVD reaction.

Also, there is provided a surface treatment method comprising: a conveying step of loading and conveying a product produced by fabricating one or more members; and a deposition layer forming step forming a deposition layer on a surface of the conveyed product using a PVD reaction.

In addition, there is provided a surface treatment system comprising: a conveying unit for loading and conveying a heat exchanger; and a surface treatment unit for forming a deposition layer on a surface of the object of surface treatment conveyed by the conveying unit.

Also, there is provided a surface treated product which is treated by a surface treatment method comprising a conveying step for loading and conveying a processed product made using one or more members and a deposition layer forming step for forming a deposition layer on a surface of the conveyed object of surface treatment using a CVD reaction.

In addition, there is provided a product which is surface treated by a surface treatment method comprising a conveying step for loading and conveying, a processed product made by one or more members, and a deposition layer forming step for forming a deposition layer on a surface of the conveyed object of surface treatment using a PVD reaction.

### BRIEF DESCRIPTION OF THE DRAWINGS

FIG. 1 is a plane view showing a general heat exchanger used in a refrigerator;

FIG. 2 is a schematic view showing a structure of a surface treatment system according to the present invention; and

FIG. 3 is a view showing a conveying path of a carrier in the surface treatment system in FIG. 2.

### MODES FOR CARRYING OUT THE PREFERRED EMBODIMENTS

Hereinafter, a surface treatment system, a surface treatment method and a product produced by the surface treatment method according to the present invention will be described in detail with reference to accompanying Figures.

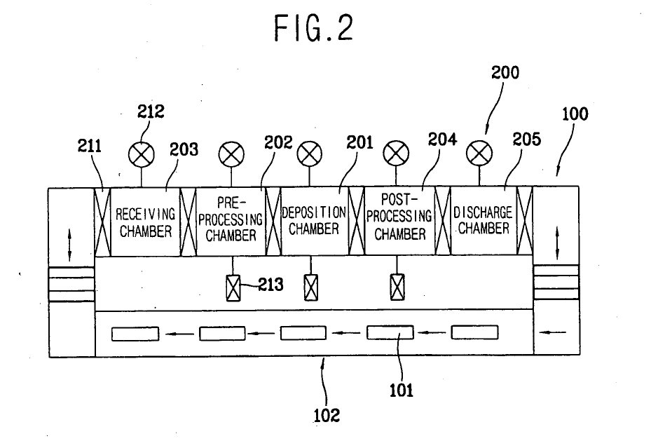

FIG. 2 is a brief view showing a structure of the surface treatment system according to the present invention.

As shown therein, the surface treatment system according to the present invention comprises: a conveying unit 100 for loading and conveying a processed object of surface treatment constructed by one or more members; and a surface treatment unit 200 forming a deposition layer on surface of the object of surface treatment conveyed by the conveying unit 100.

The surface treatment unit 200 which forms the deposition layer on the surface of the object of surface treatment comprises a deposition chamber 201 for forming the deposition layer on the surface of the object of surface treatment.

A method for forming the deposition layer on the surface of the conveyed object of surface treatment can be divided into a method forming the deposition layer using a chemical vapor deposition (CVD) reaction, and a method forming the deposition layer using a physical vapor deposition (PVD) reaction.

The method forming the deposition layer using the CVD forms the deposition layer using plasma polymerization reaction, and the method forming the deposition layer using the PVD forms the deposition layer using a sputtering method, etc.

In the embodiment of the present invention, the method forming the deposition layer using the plasma polymerization method, which is a kind of CVD reaction, is used, but the PVD method also can be used.

That is, the deposition chamber 201 is sealed by a chamber opening/closing means 211 and O-ring during the reaction, and a vacuum degree required by the deposition reaction is maintained using a pump 212. In addition, the deposition layer having a certain property, such as hydrophilicity, hydrophobicity or corrosion resistance, etc is formed on the surface of the object of surface treatment using the plasma polymerization reaction generated by injecting reaction gas into the deposition chamber 201 and applying electric power to electrodes (not shown) installed in the deposition chamber 201. Also, a plurality of deposition chambers 201 for different surface treatments may be constructed as needed.

The surface treatment unit 200 further includes a preprocessing chamber 202 for preprocessing the surface of the object of surface treatment before the deposition layer is formed on the surface of the object of surface treatment, and may include additionally a receiving chamber 203 for receiving a carrier 101 on which the object of surface treatment is mounted.

Also, the surface treatment unit 200 further includes a post-processing chamber 204 for post-processing the surface of the object of surface treatment on which the deposition layer is formed, and may include additionally a discharge chamber 205 for discharging the carrier 101 on which the object of surface treatment is mounted.

Meanwhile, the receiving chamber 203, the preprocessing chamber 202, the deposition chamber 201, the post-processing chamber 204 and the discharge chamber 205 constructing the surface treatment unit are sequentially disposed and opened/closed by chamber opening/closing means respectively. And the chambers are sealed by a sealing means such as O-ring.

The conveying unit 100 comprises a carrier 101 for loading the object of surface treatment, and a conveying device 102 for conveying the carrier 101.

The carrier 101 may be plural, and the carrier 101 coveys the object of surface treatment loaded thereon along with a conveying path of the conveying unit 100 sequentially.

The conveying device 102 uses a driving device such as a motor and a guide, and moves the carrier 101 sequentially along with the conveying path.

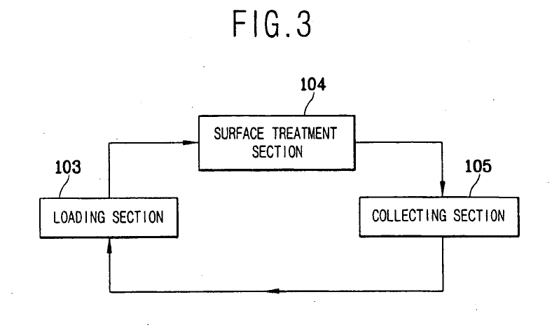

FIG. 3 is a view showing the convey path of the carrier in the surface treatment system according to the present invention.

As shown therein, the convey path, on which the carrier is moved, comprises a loading section 103 on which the object of surface treatment is loaded on the carriers 101, a surface treatment section 104 positioned on the surface treatment unit 200 and connected to the loading section 103, and a collecting section 105 connected between the surface treatment section 104 and the loading section 103 for collecting the object of surface treatment loaded on the carriers 101.

Meanwhile, operations of the surface treatment system according to the present invention having above structure will be described as follows.

To begin with, the object of surface treatment in the present invention is a product processed using one or more members, and the processing method can be divided into an assembling fabrication, a molding fabrication, or a mechanical fabrication etc.

Also, the object of surface treatment is not a member which is processed as a product after forming the deposition layer on the surface of the member, but a product processed using one or more members.

Also, the object of surface treatment is generally a metal material, and especially, a heat exchanger used in a refrigerator and in an air conditioner can be an example of the object of surface treatment.

That is, fins which are processed to be used in the heat exchanger, or the heat exchanger 10 comprising a refrigerant pipe 11 having a passage of refrigerant and a plurality of fins 13 coupled to the refrigerant pipe can be the object of surface treatment.

Also, the deposition layer formed on the object of surface treatment is able to have various properties such as hydrophilicity, hydrophobicity, corrosion resistance, heat resistance, abrasion resistance, etc. according to conditions that the object of surface treatment is used.

Operations of the surface treatment system having above structure will be described as follows. The object of surface treatment is loaded on a plurality of carriers 101 moving sequentially and continuously in the loading section 103. And the carriers 101 are moved continuously and sequentially by the conveying device 102.

The object of surface treatment loaded on the carriers 101 comes to the surface treatment section 104 according to the movement of the carriers 101, and passes the receiving chamber 203 and undergoes the preprocessing for forming the deposition layer in the preprocessing chamber 202, such as cleaning, etc.

The object of surface treatment which is pre-processed in the preprocessing chamber 202 is moved to the deposition chamber 201 by the movement of the carriers 101, and the deposition layer is formed on the surface of the object of surface treatment by a deposition reaction which is set advance so that the deposition layer of required properties can be formed.

The object of surface treatment on which the deposition layer is formed is moved to the post-processing chamber 204 by the movement of the carriers 101, and undergoes a process after forming the deposition layer in the post-processing chamber 204, and then, comes into the collecting section 105 as passing the discharge chamber 205.

The respective chambers are sealed by using opening/closing means (not shown) and sealing means (not shown) after the carriers 101 come in, and then, is opened by using the opening/closing means after the respective processes are completed, to move the carriers 101.

The object of surface treatment which reaches to the collecting section 105 by the movement of the carriers 101 is collected by an additional device or an added collecting device, and thereby, the surface treatment processes for making the surface properties suitable for the usage condition are completed.

Also, the carriers 101 having no object of surface treatment are moved to the loading section 103 by the conveying device 102 again to load another object of surface treatment, and moved toward the surface treatment section again, and thereby, the surface treatment processes are performed continuously.

That is, the massive surface treatments can be performed continuously as repeating the above processes. Also, the surface treatment system comprises a controlling device to control the respective processes.

Meanwhile, the present invention provides a surface treatment method for treating a surface of a product fabricated using one or more members. And the surface treatment method according to the present invention comprises a conveying step for loading and conveying a product which is produced by fabricating one or more members, and a deposition layer forming step for forming the deposition layer on a surface of the conveyed product using the deposition reaction.

The surface treatment method may further comprises a fabrication step for producing the product by coupling a plurality of members before the conveying step. The fabrication step is a step fabricating a product by coupling a plurality of members by assembling, mechanical fabrication or molding.

The conveying step comprises a loading step for loading the product on the carriers, and a carrier conveying step for conveying the carriers. The conveying path of the carriers comprises a loading section for loading the product on the carriers, a surface treatment section installed on the surface treatment unit and connected to the loading section, and a collecting section connected between the surface treatment section and the loading section for collecting the product loaded on the carriers. The plurality of carriers are conveyed continuously and sequentially.

Also, a preprocessing step for preprocessing the surface of the product can be added before the deposition layer forming step, and a post-processing step for post-processing the product on which the deposition layer is formed can be added after the deposition layer forming step.

According to the present invention, the massive surface treatment can be performed so that the deposition layer can be formed on the entire surfaces of the members consisting of the product by treating the surface of the product comprising one or more members for forming the deposition layer continuously, and thereby, the surface treatment system according to the present invention is able to improve a productivity.

Also, the deposition layer damage which may be generated in the fabrication process of the product can be prevented by treating the surface of the fabricated product. In addition, the product can be suitable for the conditions more easily by treating the entire surface of the product.

Especially, advantages of the present invention can be identified by comparing to following comparative example.

### COMPARATIVE EXAMPLE

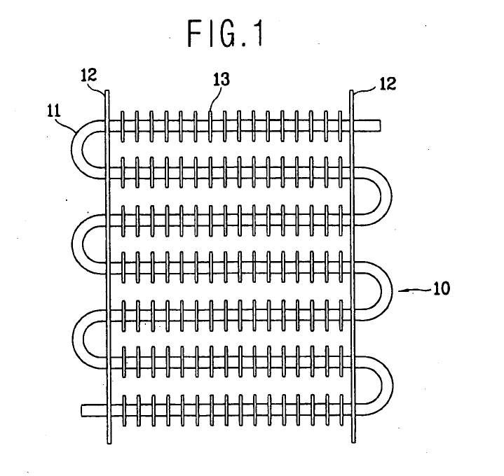

The heat exchanger comprising the fins and the refrigerant pipe used in the refrigerator shown in FIG. 1 was used as the object of surface treatment. Ratios of the fins and the refrigerant pipe for entire heat transfer area were 85% and 15% in entire heat transmitting area, respectively.

Water was sprayed to the heat exchanger having the fins which was fabricated using the surface treated member to have hydrophilicity, and to the heat exchanger which was surface treated by the surface treatment system according to the present invention, and then, water amount remained on the surfaces of the heat exchangers are measured after 5 minutes had passed.

There was 57 g of remained water in case of the heat exchanger having the fins fabricated using the surface treated member, and there was 37 g of remained water in case of the heat exchanger which was surface treated to be hydrophilic by the surface treatment system according to the present invention.

Therefore, the product which is surface treated by the surface treatment system according to the present invention can suit to the usage condition more effectively than that of the conventional art.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

1. A surface treatment system comprising:
a conveying unit for loading and conveying an object of surface treatment including one or more members which are finished manufacturing; and
a surface treatment unit for forming deposition layer on a surface of the object of surface treatment conveyed by the conveying unit using a chemical vapor deposition (CVD) reaction.

2. The system of claim 1, wherein the object of surface treatment comprises a plurality of members, and the plurality of members are coupled to each other.

3. The system of claim 2, wherein the plurality of members are coupled to each other by assembling.

4. The system of claim 1, wherein the members are finished to undergo a mechanical process.

5. The system of claim 1, wherein the members are finished to undergo a molding process.

6. The system of claim 1, wherein the members are metal materials.

7. The system of claim 1, wherein the surface treatment object is a plurality of heat transfer fins of a heat exchanger.

8. The system of claim 1, wherein the object of surface treatment is a heat exchanger.

9. The system of claim 8, wherein the heat exchanger comprises:
a refrigerant pipe having a passage of refrigerant; and
a plurality of heat transfer fins coupled to the refrigerant pipe.

10. The system of claim 1, wherein the deposition layer formed on the surface of the object of surface treatment has hydrophilicity.

11. The system of claim 1, wherein the deposition layer formed on the surface of the surface treatment object has hydrophobicity.

12. The system of claim 1, wherein the deposition layer formed on the surface of the surface treatment object has corrosion resistance.

13. The system of claim 1, wherein the conveying unit comprises:
a carrier for loading the surface treatment object; and
a conveying device for conveying the carrier.

14. The system of claim 13, wherein the conveying unit further comprises a conveying path for conveying the carrier.

15. The system of claim 14, wherein the conveying path comprises:
a loading section for loading the surface treatment object on the carrier;
a surface treatment section installed on the surface treatment unit and connected to the loading section; and
a collecting section connected between the surface treatment section and the loading section for collecting the surface treatment object loaded on the carrier.

16. The system of claim 13, wherein the carrier is constructed to be plural, and conveyed continuously and sequentially.

17. The system of claim 1, wherein the surface treatment unit comprises a deposition chamber for forming the deposition layer on the surface of the object of surface treatment using CVD reaction.

18. The system of claim 17, wherein the CVD reaction is a plasma deposition reaction.

19. The system of claim 17, wherein the surface treatment unit further includes a preprocessing chamber for preprocessing the surface of the object of surface treatment before the deposition layer is formed on the surface of the object of surface treatment.

20. The system of claim 19, wherein the preprocessing chamber further includes a receiving chamber for receiving the carrier on which the object of surface treatment.

21. The system of claim 17, wherein the surface treatment unit further comprises a post-processing chamber for post-processing the surface of the object of surface treatment on which the deposition layer is formed.

22. The system of claim 21, wherein the post-processing chamber further includes a discharge chamber for discharging the carrier on which the post-processed surface treatment object is loaded.

23. A surface treatment system comprising:
a conveying unit for loading and conveying an object of surface treatment comprising one or more processed members; and
a surface treatment unit for forming a deposition layer on a surface of the object of surface treatment conveyed by the conveying unit using a physical vapor deposition (PVD) reaction.

24. A surface treatment method comprising:
a conveying step for loading and conveying a product produced by processing one or more members; and
a deposition layer forming step for forming a deposition layer on a surface of the conveyed product using CVD reaction.

25. The method of claim 24, further comprising a processing step for producing the product by coupling a plurality of members before the conveying step.

26. The method of claim 25, wherein the product is produced by coupling the plurality of members using assembling process.

27. The method of claim 24, wherein the product is processed by mechanical process.

28. The method of claim 24, wherein the product is processed by molding process.

29. The method of claim 24, wherein the members are metal materials.

30. The method of claim 24, wherein the product is a plurality of heat transfer fins processed to be used in a heat exchanger.

31. The method of claim 24, wherein the product is a heat exchanger.

32. The method of claim 31, wherein the heat exchanger comprises:
a refrigerant pipe having a passage of refrigerant; and
a plurality of heat transfer fins coupled to the refrigerant pipe.

33. The method of claim 24, wherein the deposition layer forming step forms the deposition layer having hydrophilicity on a surface of the product.

34. The method of claim 24, wherein the deposition layer forming step forms the deposition layer having hydrophobicity on a surface of the product.

35. The method of claim 24, wherein the deposition layer forming step forms the deposition layer having corrosion resistance on a surface of the product.

36. The method of claim 24, wherein the conveying step comprises:
a loading step for loading the product on a carrier; and
a carrier conveying step for conveying the carrier.

37. The method of claim 35, wherein the carrier is constructed to be plural, and conveyed continuously and sequentially.

38. The method of claim 24, further comprising a preprocessing step for preprocessing the surface of the product before the deposition layer forming step.

39. The method of claim 24, further comprising a post-processing step for post-processing the surface of the product on which the deposition layer is formed after the deposition layer forming step.

40. A surface treatment method comprising:
a conveying step for loading and conveying a product produced by processing one or more members; and
a deposition layer forming step for forming a deposition layer on a surface of the conveyed product using a PVD reaction.

41. A surface treatment system comprising:
a conveying unit for loading and conveying a heat exchanger; and
a surface treatment unit for forming deposition layer on a surface of the heat exchanger conveyed by the conveying unit.

42. The system of claim 41, wherein the deposition layer is formed using a CVD reaction.

43. The system of claim 42, wherein the CVD reaction is a plasma polymerizing reaction.

44. The system of claim 41, wherein the conveying unit comprises a plurality of carriers which are conveyed continuously and sequentially and a conveying device for conveying the plurality of carriers.

45. The system of claim 41, wherein the deposition layer is formed by using a PVD reaction.

46. A product of which surface is treated by a surface treatment method comprising a conveying step for loading and conveying a product including one or more processed members, and a deposition layer forming step for forming a deposition on a surface of the produce using a CVD reaction.

47. The product of claim 46, being a heat exchanger.

48. The product of claim 46, being a plurality of heat transfer fins of a heat exchanger.

49. A product of which surface is treated by a surface treatment method comprising a conveying step for loading and conveying a product including one or more processed members, and a deposition layer forming step for forming a deposition on a surface of the produce using a PVD reaction.

50. The produce of claim 49, wherein the PVD reaction is a physical vapor deposition reaction using sputtering.
